(19) United States
(12) Patent Application Publication
(10) Pub. No.: US 2016/0343554 A1
(43) Pub. Date: Nov. 24, 2016

(54) OXIDE SINTERED BODY, METHOD FOR PRODUCING SAME AND SPUTTERING TARGET

(71) Applicant: IDEMITSU KOSAN CO., LTD., Tokyo (JP)

(72) Inventors: Shigekazu TOMAI, Sodegaura-shi (JP); Kazuyoshi INOUE, Sodegaura-shi (JP); Kazuaki EBATA, Sodegaura-shi (JP); Masatoshi SHIBATA, Sodegaura-shi (JP); Futoshi UTSUNO, Sodegaura-shi (JP); Yuki TSURUMA, Sodegaura-shi (JP); Yu ISHIHARA, Sodegaura-shi (JP)

(73) Assignee: IDEMITSU KOSAN CO., LTD., Tokyo (JP)

(21) Appl. No.: 15/107,993

(22) PCT Filed: Dec. 18, 2014
(86) PCT No.: PCT/JP2014/006331

§ 371 Date: Jun. 24, 2016

(30) Foreign Application Priority Data
Dec. 27, 2013 (JP) 2013-272384

(51) Int. Cl. H01J 37/34; C23C 14/34; H01L 29/786; C23C 14/08; C04B 35/01; C04B 35/64

(52) U.S. Cl. CPC H01J 37/3429; C04B 35/01; C04B 35/64; H01L 29/7869; C23C 14/086; C23C 14/083; C23C 14/08; C23C 14/3414; C04B 2235/3286; C04B 2235/3222; C04B 2235/3224; C04B 2235/3225; C04B 2235/3229; C04B 2235/602; C04B 2235/6567

(57) ABSTRACT

An oxide sintered body comprising a bixbyite phase composed of In₂O₃ and an A₃B₅O₁₂ phase (wherein A is one or more elements selected from the group consisting of Sc, Y, La, Ce, Pr, Nd, Pm, Sm, Eu, Gd, Tb, Dy, Ho, Er, Tm, Yb and Lu, and B is one or more elements selected from the group consisting of Al and Ga).

### TECHNICAL FIELD

The invention relates to an oxide sintered body used as a raw material for obtaining an oxide semiconductor thin film of a thin film transistor (TFT) used in a display or the like such as a liquid crystal display or an organic EL display by a vacuum film forming process such as a sputtering method, a production method thereof, a sputtering target and a thin film transistor obtained therefrom.

### BACKGROUND ART

Since an amorphous oxide semiconductor used in a TFT has a higher carrier mobility as compared with general-purpose amorphous silicon (a-Si), has a large optical band gap and can be formed at low temperatures, the application thereof in a next-generation display that requires an increase in size, high resolution and high-speed driving or a resin substrate having low heat resistance or the like is hoped for. In forming the above-mentioned oxide semiconductor (film), a sputtering method in which a sputtering target composed of the same material as that of the oxide semiconductor film is preferably used. The reason therefor is that, as compared with a thin film formed by an ion-plating method, a vacuum deposition method or an electron beam deposition method, a thin film formed by a sputtering method is excellent in in-plane uniformity of component composition, thickness or the like in the film surface direction, and as a result, a thin film having the same component composition as that of a sputtering target can be formed. Normally, a sputtering target is formed by mixing oxide powder, and sintering the mixture, followed by mechanical processing.

An In—Ga—Zn—O amorphous oxide semiconductor containing In has been mostly developed as the composition of an oxide semiconductor used in a display (see Patent Documents 1 to 4). Further, in recent years, in order to attain high mobility or improve reliability of a TFT, an attempt has been made to use In as a main component and to change the kind or concentration of elements to be added (see Patent Document 5).

Further, Patent Document 6 reports an In—Sm-based sputtering target.

### RELATED ART DOCUMENTS

### Patent Documents

### Patent Document 1: JP-A-2008-214697

### Patent Document 2: JP-A-2008-163441

### Patent Document 3: JP-A-2008-163442

### Patent Document 4: JP-A-2012-144410

### Patent Document 5: JP-A-2011-222557

### Patent Document 6: WO2007/010702

### SUMMARY OF THE INVENTION

A sputtering target used for production of an oxide semiconductor film for a display and an oxide sintered body that is the raw material thereof are desired to be excellent in conductivity and to have a high relative density. Further, taking into consideration mass production on a large-sized substrate, production cost or the like, it is desirable to provide a sputtering target that enables stable production not by a radio frequency (RF) sputtering but by a direct current (DC) sputtering that can easily attain high-speed film formation. However, by adding desirable elements in order to improve mobility or reliability of a TFT, the resistance of a target may be increased, resulting in occurrence of abnormal discharge or generation of particles.

In order to enhance mobility or reliability, it is important to decrease traps present in the energy gap of an oxide semiconductor. As one of technologies therefor, a method can be given in which water is introduced into a chamber during sputtering, thereby to realize more effective oxidization. Water is decomposed in plasma, and becomes OH radicals that show significantly strong oxidizing power, and hence have an effect of decreasing traps in an oxide semiconductor. However, a process of introducing water has problems that it requires sufficient removal in advance of oxygen or nitrogen that has been dissolved in water, as well as a new countermeasure such as prevention of corrosion of a piping has become necessary.

The invention has been made in view of the above-mentioned circumstances, and is aimed at providing an oxide semiconductor sintered body and a sputtering target that are preferably used in production of an oxide semiconductor film for a display, has high conductivity and is excellent in discharge stability.

According to the invention, the following oxide sintered body or the like are provided.

1. An oxide sintered body comprising a bixbyite phase composed of In₂O₃ and an A₃B₅O₁₂ phase (wherein A is one or more elements selected from the group consisting of Sc, Y, La, Ce, Pr, Nd, Pm, Sm, Eu, Gd, Tb, Dy, Ho, Er, Tm, Yb and Lu, and B is one or more elements selected from the group consisting of Al and Ga).
2. The oxide sintered body according to 1, wherein A is one or more elements selected from the group consisting of Y, Ce, Nd, Sm, Eu and Gd.
3. The oxide sintered body according to 1 or 2, wherein either one or both of the element A and the element B is (are) in a substitutional solid solution state in the bixbyite phase.
4. The oxide sintered body according to any one of 1 to 3, wherein the atomic ratio of indium, the element A and the element B contained in the oxide sintered body, (A+B)/(In+A+B), is 0.01 to 0.50.
5. The oxide sintered body according to any one of 1 to 4, wherein the electrical resistivity is 1 mΩcm or more and 1000 mΩcm or less.
6. A method for producing an oxide sintered body comprising the steps of:

preparing mixture powder by mixing raw material powder comprising indium, raw material powder comprising A which is one or more elements selected from the group consisting of Sc, Y, La, Ce, Pr, Nd, Pm, Sm, Eu, Gd, Tb, Dy, Ho, Er, Tm, Yb and Lu and raw material powder comprising B which is one or more elements selected from the group consisting of Al and Ga;

shaping the mixture powder to produce a shaped body; and

firing the shaped body at 1200° C. to 1650° C. for 10 hours or longer.

7. The method for producing an oxide sintered body according to 6, wherein an atomic ratio (A+B)/(In+A+B) of the mixture powder is 0.01 to 0.50.
8. A sputtering target obtained by using the oxide sintered body according to any one of 1 to 5.
9. An oxide thin film formed by using the sputtering target according to 8.
10. A thin film transistor in which the oxide thin film according to 9 is used.
11. The oxide sintered body according to any one of 1 to 5, wherein the maximum particle size of crystals of the A₃B₅O₁₂ phase is 20 μm or less.
12. The thin film transistor according to 10, wherein the thin film transistor is a channel-doped type thin film transistor.
13. An electronic apparatus in which the thin film transistor according to 10 or 12 is used.

According to the invention, it is possible to provide an oxide sintered body and a sputtering target that are preferably used in an oxide semiconductor film for a display, as well as to provide a sputtering target that exhibits high conductivity and is excellent in discharge stability.

### BRIEF DESCRIPTION OF THE DRAWINGS

FIG. 1 is a view showing the results of an X-ray diffraction analysis of the oxide sintered body of Example 1;

FIG. 2 is a view showing the results of an X-ray diffraction analysis of the oxide sintered body of Example 2;

FIG. 3 is a view showing the results of a measurement by an electron microanalyzer of the oxide sintered body of Example 1;

FIG. 4 is a view showing the results of a measurement by an electron microanalyzer of the oxide sintered body of Example 2; and

FIG. 5 is a view showing the relationship between the mobility and the voltage between the gate-source electrodes of the thin film transistors of Examples 1 and 2.

### MODE FOR CARRYING OUT THE INVENTION

The oxide sintered body of the present invention comprises a bixbyite phase composed of In₂O₃ and an A₃B₅O₁₂ phase (wherein A is one or more elements selected from the group consisting of Sc, Y, La, Ce, Pr, Nd, Pm, Sm, Eu, Gd, Tb, Dy, Ho, Er, Tm, Yb and Lu, and B is one or more elements selected from the group consisting of Al and Ga).

By the sputtering target prepared by using the oxide sintered body of the invention, an oxide semiconductor thin film for a high-performance TFT that is required for a next-generation display can be obtained in a high yield. Further, in the oxide sintered body of the invention, even when desired elements are added in order to enhance mobility or reliability, since the resistance of the resulting target can be suppressed low, it is possible to obtain a target that is excellent in discharge stability.

The A₃B₅O₁₂ phase can be called as garnet or a garnet phase.

Presence of the In₂O₃ phase, i.e. garnet in the oxide sintered body of the invention can be confirmed by means of an X-ray diffraction apparatus (XRD). Specifically, it can be confirmed by collating the results of an X-ray diffraction analysis with the ICDD (International Centre for Diffraction Data) card. The In₂O₃ phase shows a pattern of No. 6-416 of the ICDD card. As for Sm₃Ga₅O₁₂ (garnet), it shows a pattern of No. 71-0700 of the ICDD card.

The garnet phase is electrically insulative. However, due to dispersion in a bixbyite phase having high conductivity in the form of a sea-island structure, electrical resistivity of a sintered body can be kept low.

A includes Sc, Y, La, Ce, Pr, Nd, Pm, Sm, Eu, Gd, Tb, Dy, Ho, Er, Tm, Yb and Lu. Due to A being composed of these elements, it is possible to obtain an oxide semiconductor having a higher mobility from the oxide sintered body of the invention.

In respect of obtaining a larger On/Off properties in a transistor, A is preferably Y, Ce, Nd, Sm, Eu and Gd, with Y, Nd, Sm and Gd being more preferable.

A may be used singly or in combination of two or more.

B includes Al and Ga. Due to B being composed of these elements, it is possible to increase the conductivity of a target formed of the oxide sintered body of the invention.

B may be used singly or in combination of two or more.

In the oxide sintered body of the invention, as for the elements A and B that do not form a garnet phase, they may be solid solution-substituted in a bixbyite phase that is a low-resistance matrix phase singly or in combination.

In the bixbyite phase, the solid solution limit of A and B (in total) is 10 at % or less relative to the In element (the atomic ratio (A+B)/(In+A+B) is 0.10 or less). If the solid solution limit is 10 at % or less, the resistance of the target can be within an appropriate range. Further, it is possible to enable DC discharge to occur, as well as to suppress abnormal discharge.

In the oxide sintered body of the invention, the element A and the element B that do not form the garnet phase are solid solution-substituted in a bixbyite phase that is a low-resistance matrix phase singly or in combination. This can be confirmed by characteristic X-rays detected from the element A and/or B in the bixbyite phase by means of EPMA.

In the oxide sintered body of the invention, the atomic ratio of indium, element A and element B, (A+B)/(In+A+B), is preferably 0.01 to 0.50, more preferably 0.015 to 0.40, and further preferably 0.02 to 0.30.

When (A+B)/(In+A+B) exceeds 0.50, the network of the bixbyite phase is interrupted, and as a result, the target resistance is increased, whereby discharge during sputtering becomes instable or particles tend to be generated.

On the other hand, if the (A+B)/(In+A+B) is less than 0.01, the carrier concentration of the oxide semiconductor produced by sputtering is increased, whereby a TFT may be in a normally-on state.

The In/(In+A+B) is preferably 0.50 or more and 0.99 or less, more preferably 0.60 or more and 0.985 or less, and further preferably 0.70 or more and 0.98 or less.

The atomic ratio of each element contained in a sintered body can be obtained by quantitatively analyzing contained elements by an Inductively Coupled Plasma Atomic Emission Analysis apparatus (ICP-AES).

Specifically, the solution specimen is allowed to be in the form of mist by means of a nebulizer, and then introduced into argon plasma (about 5000 to 8000° C.). Then, the elements in the specimen were excited by absorbing thermal energy, and after the orbit electrons are transferred from the ground state to an orbit having a high energy level, the elements are then transferred to an orbit having a lower energy level.

At this time, difference in energy is irradiated as light to emit light. This light has a wavelength peculiar to the element (spectral line). Therefore, presence of the element can be confirmed by the presence or absence of a spectral line (qualitative analysis).

Further, since the size of each spectral line (emission intensity) is in proportion to the number of elements in the specimen, the concentration of the specimen can be obtained by comparing with a standard solution with a known concentration (quantitative analysis).

After specifying the contained elements by qualitative analysis, the content is obtained by quantitative analysis. From the results, the atomic ratio of each element is obtained.

The oxide sintered body of the invention may contain other metal elements than In, A and B mentioned above or inevitable impurities within a range that does not impair the effects of the invention.

In the oxide sintered body of the invention, as other metal elements, Sn and/or Ge may be appropriately added. The amount added is normally 50 to 30000 ppm, preferably 50 to 10000 ppm, more preferably 100 to 6000 ppm, further preferably 100 to 2000 ppm, with 500 to 1500 ppm being particularly preferable. If Sn and/or Ge are/is added within the above-mentioned concentration range, In in the bixbyite phase is partially solid solution-substituted by Sn and/or Ge. As a result, electrons as a carrier generate, whereby resistance of the target can be decreased. Contents of other metal elements contained in the sintered body can also be obtained by quantitative analysis by Inductively Coupled Plasma Atomic Emission Analysis apparatus (ICP-AES) as in the case of In, A and B.

In order to increase the mobility of an oxide semiconductor obtained by using the oxide sintered body of the invention, it is preferable to add a positive tetravalent element such as Sn in a concentration of 50 to 30000 ppm.

In general, mobility of an oxide semiconductor is increased by increasing carrier concentration generated due to oxygen deficiency. However, this oxygen deficiency tends to change by bias stress or heat stress test, and as a result, a problem arises in operational reliability.

By addition of a positive tetravalent element according to the invention, oxygen deficiency can be sufficiently reduced by inclusion of the elements A and B that stably bond with oxygen, and carriers in a semiconductor channel can be controlled (channel doping). As a result, it is possible to attain high mobility and operational reliability.

In order to allow the effects of channel doping to be exhibited sufficiently, the content of a positive tetravalent element such as Sn is preferably 100 to 15000 ppm, further preferably 500 to 10000 ppm, and particularly preferably 1000 to 7000 ppm. If the content of a positive tetravalent element exceeds 30000 ppm, the carrier concentration may be increased excessively to cause a normally-on state. If the content of the positive tetravalent element is less than 50 ppm, while the resistance of the target is decreased, the effect of controlling the carrier concentration in the channel is not exhibited.

If the substrate with an oxide semiconductor film being formed thereon is quickly heated, e.g. is directly input in a furnace heated to 300° C., radially-shaped crystals tend to grow. Further, if the temperature is elevated slowly, i.e. 10° C./min or lower, facet-shaped crystals tend to grow. The effect of channel doping depends on the crystallization temperature rather than the crystal form. Therefore, it is important to determine the crystallization temperature and crystallization time while confirming the effect of channel doping.

The crystallization (annealing) conditions may be appropriately selected within a range of crystallization temperature of 250 to 450° C. and crystallization time of 0.5 to 10 hours, while checking the effect of channel doping. It is more preferred that crystallization be conducted at 270 to 400° C. for 0.7 to 5 hours.

If the crystallization temperature or the crystallization time is insufficient, the efficiency of doping to channel regions may be lowered. If the crystallization temperature or the crystallization time is excessive, in the case of a structure in which an electrode has been stacked in advance, adhesiveness with the electrode may be lowered.

In the oxide sintered body of the invention, in all metal elements, the concentration of In, the element A and the element B or In, the element A, the element B and metal elements of Sn and Ge may be 90 at % or more, 95 at % or more, 98 at % or more and 100 at %.

The electrical resistivity of the oxide sintered body of the invention is preferably 1 mΩcm or more and 1000 mΩcm or less, more preferably 5 mΩcm or more and 800 mΩcm or less, with 10 mΩcm or more and 500 mΩcm or less being further preferable.

When the electrical resistivity exceeds 1000 mΩcm, abnormal discharge may occur during sputtering discharge or particles may tend to be generated from a target. Occurrence of abnormal discharge can be avoided by using RF sputtering, but power equipment and film-forming rate become problematic, and hence, use of RF sputtering is not preferable in respect of production. Similarly, although abnormal discharge can be solved by using AC sputtering, use of AC sputtering is not preferable since control of widening of plasma becomes complicated. Meanwhile, the electrical resistivity of a sintered body can be measured by the four probe method (JIS R1637) by using a resistivity meter (Loresta, manufactured by Mitsubishi Chemical Corporation).

The maximum particle size of the crystals in the garnet phase in the sintered body used in the invention is preferably 20 μm or less, more preferably 10 μm or less. If the maximum crystal size exceeds 20 μm, pores or cracks may be generated in the sintered body due to abnormal growth of particles, causing breakage. The lower limit of the maximum particle size is preferably 1 μm. If the lower limit is less than 1 μm, the sea-island structure relationship of bixbyite and garnet phase may become unclear, whereby electrical resistance of the sintered body may be increased.

The maximum particle size of the crystal of the garnet phase in the sputtering target is obtained as follows. If the sputtering target has a circular shape, at five locations in total, i.e. the central point (one) and the points (four) which are on the two central lines crossing orthogonally at this central point and are middle between the central point and the peripheral part, are used. If the sputtering target has a square shape, at five locations in total, i.e. the central point (one) and middle points (four) between the central point and the corner of the diagonal line of the square are used. The longest diameter of a crystal that has the longest diameter among crystals observed within 100-μm square area at each of these five points is measured. The maximum particle size is expressed with the average value of the longest diameters as measured for a crystal that has the longest diameter among crystals observed within each of the square area at the five points. As for the maximum particle size, the longest diameter of the crystal particle is measured. The crystal particles can be observed by the scanning electron microscopy (SEM).

In the production method of the invention, an oxide sintered body can be produced by passing through a step of mixing raw material powder comprising indium, raw material powder comprising the element A and the raw material powder comprising the element B to prepare a mixture powder, a step of shaping the mixture powder to produce a shaped body and a step of firing the shaped body.

The elements A and B are as mentioned above.

As the raw material powder, oxide powder is preferable.

The average particle size of the raw material powder is preferably 0.1 μm to 1.2 μm, more preferably 0.5 μm to 1.0 μm or less. The average particle size of the raw material powder can be measured by a laser diffraction particle size analyzer or the like.

For example, In₂O₃ powder having an average particle size of 0.1 μm to 1.2 μm, powder of an oxide of the element A having an average particle size of 0.1 μm to 1.2 μm, and powder of an oxide of the element B having an average particle size of 0.1 μm to 1.2 μm can be used.

It is preferred that the raw material powder be prepared such that the atomic ratio (A+B)/(In+A+B) be 0.01 to 0.50. An atomic ratio (A+B)/(In+A+B) of 0.015 to 0.40 is more preferable, with 0.02 to 0.30 being further preferable.

No specific restrictions are imposed on the method for mixing the raw materials and shaping, and a known method can be used. For example, an aqueous solvent is compounded with the mixture of the raw material powder, the resulting slurry is mixed for 12 hours or longer. The resultant is subjected to solid-liquid separation, dried, and granulated, and subsequently, this granulated product is shaped by putting in a mold.

As for mixing, a wet or dry ball mill, a vibration mill, a beads mill or the like can be used.

The mixing time by means of a ball mill is preferably 15 hours or longer, more preferably 19 hours or longer.

When mixing is conducted, an arbitrary amount of a binder is added and while mixing. As the binder, polyvinyl alcohol, vinyl acetate or the like can be used.

Subsequently, granulated powder is obtained from the raw material powder slurry. For granulation, it is preferable to conduct freeze drying.

The granulated powder is filled in a mold such as a rubber mold, and then molded at a pressure of 100 Ma or more, for example, by metallic press molding or cold isostatic pressing (CIP), normally.

The resulting molded product is sintered at a sintering temperature of 1200 to 1650° C. for 10 hours or longer, whereby a sintered body can be obtained.

The sintering temperature is preferably 1350 to 1600° C., more preferably 1400 to 1600° C., and further preferably 1450 to 1600° C. The sintering time is preferably 10 to 50 hours, more preferably 12 to 40 hours, and further preferably 13 to 30 hours.

If the sintering temperature is less than 1200° C. or the sintering time is less than 10 hours, sintering does not proceed sufficiently. As a result, the electrical resistivity of the target may not be lowered sufficiently, causing abnormal discharge. On the other hand, if the firing temperature exceeds 1650° C. or the firing time exceeds 50 hours, an increase in average crystal particle due to significant growth of crystal particles or generation of large voids may cause, resulting in lowering in sintered body strength or occurrence of abnormal discharge.

As the sintering method used in the invention, in addition to a pressure-less sintering method, a pressure sintering such as hot pressing, oxygen pressure sintering and hot isostatic pressing or the like can be used.

In the pressure-less sintering method, a shaped body is sintered in an atmosphere or an oxidizing gas. It is preferable to conduct sintering in an oxidizing gas atmosphere. The oxidizing gas atmosphere is preferably an oxygen gas atmosphere. It is preferred that, in an oxygen gas atmosphere, an oxygen concentration be 10 to 100 vol %. In the method for producing the above-mentioned sintered body, by introducing an oxygen gas atmosphere in the temperature-elevation step, it is possible to further increase the sintered body density.

Further, as for the temperature-elevating rate for sintering, it is preferred that the temperature be elevated from 800° C. to a sintering temperature (1200 to 1650° C.) at a rate of 0.1 to 2° C./min.

In the sintered body of the invention, the temperature range above 800° C. is a range where sintering proceeds most significantly. If the temperature-elevating rate in this temperature range is slower than 0.1° C./min, the crystal particle growth may become significant, and an increase in density may not be attained. On the other hand, if the temperature-elevating rate becomes higher than 2° C./min, temperature distribution is generated in a shaped body, whereby a sintered body may be warped or broken.

The temperature-elevating rate in a range from 800° C. to a sintering temperature is preferably 0.1 to 1.3° C./min, more preferably 0.1 to 1.1° C./min.

By processing the sintered body as obtained above, the sputtering target of the invention can be obtained. Specifically, by cutting the sintered body in a shape suited to be mounted in a sputtering apparatus to obtain a sputtering target material, and by bonding the sputtering target material to a backing plate, a sputtering target can be obtained.

In the target of the invention, due to the presence of the bixbyite phase and the garnet phase, resistance can be decreased, whereby productivity can be improved.

In order to allow the sintered body to be a target material, the sintered body is ground by means of a surface grinder, for example, thereby to obtain a material having a surface roughness Ra of 0.5 μm or less.

The sputtering target of the invention has high conductivity, so that a DC sputtering method that is able to realize a high film-forming rate can be applied.

The sputtering target of the invention can be applied also to a RF sputtering method, an AC sputtering method, a pulse DC sputtering method in addition to the above-mentioned DC sputtering method. As a result, sputtering free from abnormal discharge becomes possible.

By forming a film by a sputtering method by using the above-mentioned sputtering target, it is possible to obtain a high-resistant oxide thin film.

An oxide semiconductor thin film can be prepared by a deposition method, a sputtering method, an ion plating method, a pulse laser deposition method or the like by using the above-mentioned target.

The carrier concentration of the oxide semiconductor thin film is normally 10¹⁸/cm³ or less, preferably 10¹³ to 10¹⁸/cm³, further preferably 10¹⁴ to 10¹⁸/cm³, with 10¹⁵ to 10¹⁸/cm³ being particularly preferable.

The carrier concentration of the oxide semiconductor thin film can be measured by the Hall effect measurement method.

The oxide thin film mentioned above can be used in a thin film transistor, in particular suitably used as a channel layer.

No specific restrictions are imposed on the device configuration of the thin film transistor of the invention as long as the thin film transistor has the above-mentioned oxide thin film as a channel layer, and various known device configurations can be used.

The thickness of the channel layer of the thin film transistor of the invention is normally 10 to 300 nm, preferably 20 to 250 nm.

The channel layer in the thin film transistor of the invention is normally used in an N-type region. It can be used in various semiconductor devices such as a PN-junction transistor by combining with various P-type semiconductors such as a P-type Si-based semiconductor, a P-type oxide semiconductor and a P-type organic semiconductor.

The thin film transistor of the invention can be applied to various integrated circuits such as a field effect transistor, a logic circuit, a memory circuit and a differential gain control circuit. Further, in addition to a field effect transistor, it can be applied to a static induction transistor, a schottky-barrier diode, a schottky diode and a resistance device.

As for the configuration of the thin film transistor of the invention, a known configuration such as bottom gate, bottom contact and top contact can be used without restrictions.

The bottom gate configuration is particularly advantageous since high performance can be obtained as compared with thin film transistors using amorphous silicon or ZnO. The bottom gate configuration is preferable since the number of masks at the time of production can be decreased easily and the production cost for applications such as large-sized displays can be reduced easily.

The thin film transistor of the invention can be preferably used in displays.

For large-sized displays, a channel-etch type thin film transistor having a bottom gate configuration is particularly preferable. A channel-etch type thin film transistor having a bottom gate configuration enables a panel for a display to be produced at a low cost by using a small number of photo masks during the photolithography process. Among these, a thin film transistor having a channel-etch type bottom gate configuration or a top-contact configuration is particularly preferable since properties such as mobility are excellent and hence are readily industrialized.

In the transistor properties, On/Off properties are factors determining the display performance of a display. When used as switching of a liquid crystal, it is preferred that the On/Off ratio be a number consisting of 6 digits or more. In the case of an OLED, on current is important since it is driven by current. However, as for the On/Off ratio, it is also preferred that it consist of 6 digits or more.

In the thin film transistor of the invention, it is preferred that an On/Off ratio be 1×10⁶ or more.

It is preferred that the mobility of the TFT of the invention be 5 cm²/Vs or more, with 10 cm²/Vs or more being more preferable.

It is preferred that the thin film transistor of the invention be a channel-dope type thin film transistor. A channel-dope type transistor is a transistor in which carriers of a channel are appropriately controlled not by an oxygen deficiency that is easily changed by stimulus from the outside such as atmosphere and temperature but by n-type doping, and effects of attaining both high mobility and high reliability can be obtained.

### EXAMPLES

Hereinbelow, the invention will be explained in more detail with reference to the Examples which should not be construed as limiting the gist of the invention. The invention can be implemented by appropriately modifying within the scope of the invention, and such modifications fall within the scope of the invention.

### Examples 1 to 15

### Production of Sintered Body

As raw material powders, the following oxide powders were used. The average particle size of the oxide powder was measured by a laser diffraction particle size analyzer SALD-300V (manufactured by Shimadzu Corporation). The median size D50 was employed as an average particle size for the following oxide powders.

Indium oxide powder: average particle size 0.98 μm

Gallium oxide powder: average particle size 0.96 μm

Aluminum oxide powder: average particle size 0.96 μm

Tin oxide powder: average particle size 0.95 μm

Samarium oxide powder: average particle size 0.99 μm

Yttrium oxide powder: average particle size 0.98 μm

Neodymium oxide powder: average particle size 0.98 μm

Gadolinium oxide powder: average particle size 0.97 μm

The above-mentioned oxide powders were weighed such that the oxide weight ratios shown in Tables 1 and 2 were attained. The weighed oxide powders were homogenously and finely pulverized and mixed, and granulated by a spray drying method after adding a binder for shaping. Subsequently, this raw material granulated powder was filled in a rubber mold, and subjected to press molding at 100 MPa by cold isostatic pressing (CIP).

The thus obtained shaped body was sintered in a sintering furnace at 1450° C. for 24 hours, whereby a sintered body was produced.

### [Analysis of Sintered Body]

The electrical resistivity of the obtained sintered body was measured by means of a resistivity meter (Loresta, manufactured by Mitsubishi Chemical Analytech Co., Ltd.) in accordance with the four-probe measurement (JIS R 1637). The results are shown in Table 1 and Table 2. As shown in Table 1 and Table 2, the electrical resistivity of the sintered bodies of Examples 1 to 15 were 1000 mΩcm or less.

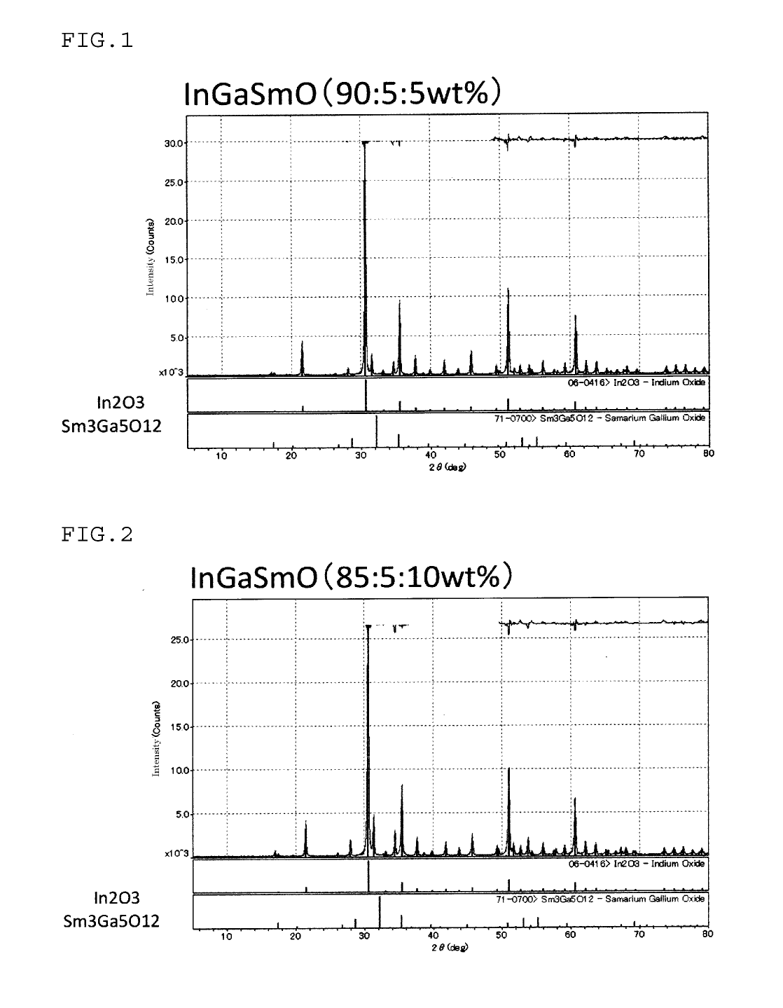

The crystal structure was examined by means of an X-ray diffraction measurement apparatus (XRD). X-ray diffraction charts of the sintered bodies obtained in Examples 1 and 2 are shown in FIGS. 1 and 2. As a result of analyzing the chart, it was revealed that the sintered bodies of Examples 1 and 2 are composite ceramics composed of In₂O₃ and Sm₃Ga₅O₁₂.

XRD was measured under the following conditions.
Apparatus: Ultima-III manufactured by Rigaku Corporation
X ray: Cu-Kα ray (wavelength 1.5406 Å, monochromatized with a graphite monochromator)
2θ-θ reflection method, continuous scanning (1.0°/min.)
sampling interval: 0.02°
slits DS, SS: ⅔°, RS: 0.6 mm

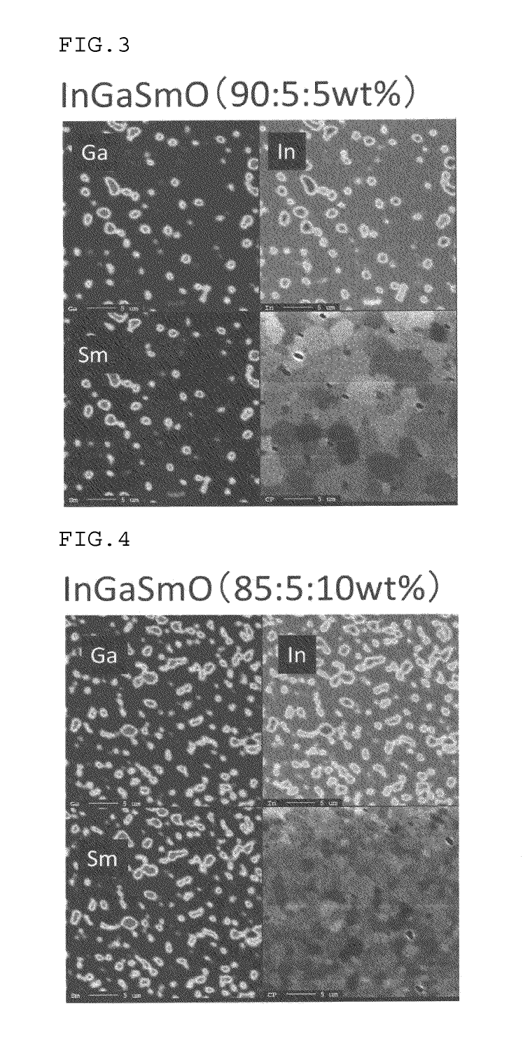

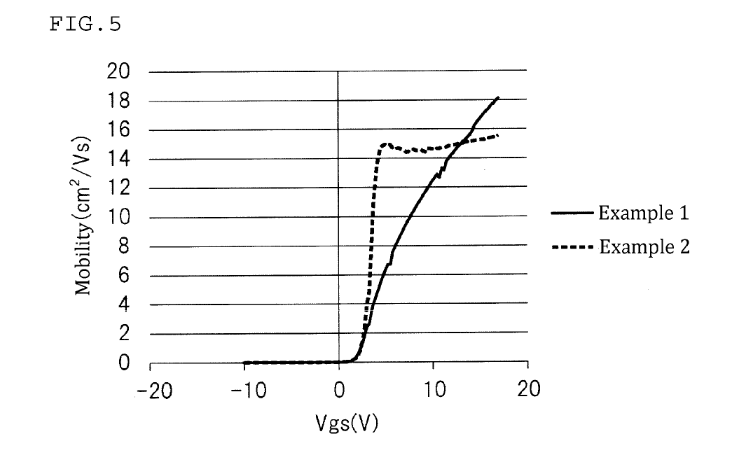

The surface of this composite ceramics was ground, and the distribution of elements was confirmed by means of an electron beam microanalyzer (EPMA). The results are shown in FIGS. 3 and 4. As a result of EPMA, it was revealed that the composite ceramics of Examples 1 and 2 had a structure in which Sm₃Ga₅O₁₂ (garnet) was dispersed in a matrix of In₂O₃ (bixbyite). Due to such dispersion of the garnet structure, it was possible to obtain a low-resistant target without inhibiting conductivity of the bixbyite phase. The crystal structure can be confirmed by the JCPDS (Joint Committee of Powder Diffraction Standards) card. The bixbyite structure of indium oxide is indicated by No. 06-0416 of the JCPDS card. The garnet structure composed of Sm₃Ga₅O₁₂ is indicated by No. 71-0700 of the JCPDS card.

The measurement conditions for EPMA are as follows:

Name of Apparatus:

JXA-8200 manufactured by JEOL Ltd.

Measurement Conditions:

Accelerating voltage: 15 kV

Irradiation current: 50 nA

Irradiation time (per one point): 50 mS

Similarly, as for the sintered bodies obtained in Examples 3 to 15, the crystal structure was examined by XRD, and the dispersion condition was examined by an EPMA measurement. As a result, it was found that the sintered bodies had a structure in which A₃B₅O₁₂ (garnet) structure was dispersed in a matrix of In₂O₃ (bixbyite). Due to such dispersion of the high-resistant phase of the garnet structure, a low-resistant target could be obtained without hindering the conductivity of the low-resistant phase.

### [Production of Sputtering Target]

The surface of the sintered bodies obtained as above was ground by means of a surface grinder in the order of #40, #200, #400 and #1000. The sides thereof were cut by using a diamond cutter. The sintered bodies thus shaped were bonded to a backing plate, thereby to obtain sputtering targets each having a diameter of 4 inches.

### [Confirmation of Presence or Absence of Abnormal Charge]

The sputtering target having a diameter of 4 inches obtained was mounted in a DC sputtering apparatus. As the atmosphere, a mixed gas obtained by adding O₂ gas to argon gas at a partial pressure of 2% was used. A continuous sputtering was conducted for 10 hours at a DC power of 200 W with the sputtering pressure being 0.4 Pa and the substrate temperature being room temperature. The variation in voltage during the sputtering was stored in data logger to confirm the presence or absence of abnormal discharge. The results are shown in Tables 1 and 2.

The above-mentioned presence or absence of abnormal discharge was determined by detecting abnormal discharge while monitoring the variation in voltage. Specifically, “abnormal discharge” is defined by the case where the voltage variation generated for a measurement time of 5 minutes is 400V±10% or more of the working voltage during sputtering operation. In particular, when the working voltage during a sputtering operation varies within a range of ±10% or more for 0.1 second, micro-arcs, which are abnormal discharge during sputtering, may generate, thereby lowering the yield of a device. Accordingly, such a sputtering target may be unsuitable for mass production.

### [Fabrication of TFT]

On the silicon substrate provided with a thermally oxidized film, an oxide semiconductor layer was formed by sputtering by using a channel-shaped metal mask. The sputtering conditions were sputtering pressure=1 Pa, oxygen partial pressure=5%, substrate temperature=room temperature. The film thickness was set to 50 nm. Then, by using a source/drain shaped metal mask, a gold electrode was formed in a thickness of 50 nm. Finally, annealing was conducted in the air at 300° C. for 1 hour, a simple, bottom gate and top contact TFT having a channel length of 200 μm and a channel width of 1000 μm was obtained. Annealing conditions were appropriately selected within a range of 250° C. to 450° C. for 0.5 hour to 10 hours while checking the effect of channel doping.

[Calculation of TFT Mobility, and on/Off Ratio]

By using a semiconductor parameter analyzer (Keithley 4200), transmission characteristics of the thin film transistors of each Example were measured at room temperature (25° C.) in the air with the light being shielded. The evaluation was conducted in a range of Vds=20V and Vgs=−10V to 20V. Subsequently, in accordance with the following formula (1) of the mobility, the mobility of the TFT when Vg=5V was calculated. As for the mobility, a higher value with a low gate voltage is preferable since it means that the TFT could be driven at a low power voltage. FIG. 5 shows the results of the measurement of the mobility relative to the voltage between the gate electrode and the source electrode in the thin film transistors of Examples 1 and 2.

$${I}_{D} = \frac{μ {WC}_{ox}}{2 L} {( {V}_{GS} - {V}_{T} )}^{2} \qquad ( 1 )$$

Here, W is a channel width, L is a channel length, Cox is a dielectric constant of the insulating film, V_{GS} is a voltage between the gate electrode and the source electrode, V_{T} is a threshold voltage and L is a channel length.

Further, Ids of Vg=−5V and Ids of Vg=10V were taken as Ioff and Ion, respectively, and Ion/Ioff was defined as On/Off ratio.

The results are shown in Tables 1 and 2.

### Comparative Examples 1 to 5

The oxide powders were weighed such that the oxide weight ratios shown in Table 3 was attained. Sintered bodies were produced in the same manner as in Example 1, and sputtering targets were prepared.

For the resulting sintered body, an analysis was conducted in the same manner as in Example 1. The results are shown in Table 3.

The sintered body of Comparative Example 1 was a mixed phase of a bixbyite phase in which Ga was in a solid solution state and a Ga₂O₃ phase.

The sintered body of Comparative Example 2 was a mixed phase of a bixbyite phase in which Al was in a solid solution state and Al₂O₃ phase.

The sintered bodies of Comparative Examples 3 and 4 showed a bixbyite single phase in which Ga is in a solid solution state.

The sintered body of Comparative Example 5 showed a bixbyite phase in which Sm is in a solid solution state.

The thus obtained target was mounted in a sputtering apparatus, and a TFT was tried to be fabricated in the same manner as in Example 1. In Table 3, in the column of abnormal discharge, “occurred” means abnormal discharge occurred during film formation, and film formation was stopped. As for the TFT mobility and the On/Off ratio, “not measured” means film formation could not be conducted due to abnormal discharge, and hence, no evaluation was conducted.

In Comparative Examples 3 to 5, abnormal discharge did not occur. However, as for the properties of the resulting TFT, the off current was high. The reason therefor is that oxidation of the semiconductor was not sufficient, a large amount of electrons were present in the channel, and the depletion layer was hardly widened even if the Off voltage was applied.

TABLE 1

| | Ex. 1 | Ex. 2 | Ex. 3 | Ex. 4 |
|---|---|---|---|---|
| Raw material oxide mixing ratio (wt %) | In₂O₃:Ga₂O₃:Sm₂O₃ = | In₂O₃:Ga₂O₃:Sm₂O₃ = | In₂O₃:Ga₂O₃:Sm₂O₃ = | In₂O₃:Al₂O₃:Sm₂O₃ = |
| | 90:5:5 | 85:5:10 | 65.7:21.9:12.4 | 92.0:5.1:2.9 |
| Composition (at %) | In:Ga:Sm = | In:Ga:Sm = | In:Ga:Sm = | In:Al:Sm = |
| | 88.8:7.3:3.9 | 84.7:7.4:7.9 | 56.9:28.1:15.0 | 83.6:12.7:3.7 |
| (A + B)/(In + A + B) | 0.112 | 0.153 | 0.431 | 0.167 |
| Bixbyite phase | In₂O₃(Ga is in solid | In₂O₃(Sm, Ga are in | In₂O₃(Sm, Ga are in | In₂O₃(Al is solid |
| | solution state) | solid solution state) | solid solution state) | solution state) |
| Garnet phase | Sm₃Ga₅O₁₂ | Sm₃Ga₅O₁₂ | Sm₃Ga₅O₁₂ | Sm₃Al₅O₁₂ |
| Maximum particle size of garnet phase | 4 | 5 | 5 | 6 |
| (μm) | | | | |
| Electrical resistivity of sintered body | 9 | 13 | 600 | 8 |
| (mΩ · cm) | | | | |
| Abnormal discharge | Not occurred | Not occurred | Not occurred | Not occurred |
| TFT mobility | 10 | 25 | 20 | 17 |
| Carrier concentration (cm⁻³) | 5.0 × 10¹⁶ | 1.0 × 10¹⁶ | 1.0 × 10¹⁶ | 8.0 × 10¹⁵ |
| On/Off ratio | >1 × 10⁶ | >1 × 10⁶ | >1 × 10⁶ | >1 × 10⁶ |

| | Ex. 5 | Ex. 6 |
|---|---|---|
| Raw material oxide mixing ratio (wt %) | In₂O₃:Al₂O₃:Sm₂O₃ = | In₂O₃:Al₂O₃:Sm₂O₃ = |
| | 88.8:5.2:6.0 | 72.9:11.2:15.9 |
| Composition (at %) | In:Al:Sm = | In:Al:Sm = |
| | 79.7:12.8:7.5 | 58.0:24.3:17.7 |
| (A + B)/(In + A + B) | 0.203 | 0.420 |
| Bixbyite phase | In₂O₃(Al is in solid | In₂O₃(Sm, Al are in |
| | solution state) | solid solution state) |
| Garnet phase | Sm₃Al₅O₁₂ | Sm₃Al₅O₁₂ |
| Maximum particle size of garnet phase | 6 | 15 |
| (μm) | | |
| Electrical resistivity of sintered body | 20 | 800 |
| (mΩ · cm) | | |
| Abnormal discharge | Not occurred | Not occurred |
| TFT mobility | 15 | 13 |
| Carrier concentration (cm⁻³) | 1.0 × 10¹⁶ | 3.0 × 10¹⁴ |
| On/Off ratio | >1 × 10⁶ | >1 × 10⁶ |

TABLE 2

| | Ex. 7 | Ex. 8 | Ex. 9 |
|---|---|---|---|
| Raw material oxide mixing ratio (wt %) | In₂O₃:Ga₂O₃:Y₂O₃ = | In₂O₃:Ga₂O₃:Nd₂O₃ = | In₂O₃:Ga₂O₃:Gd₂O₃ = |
| | 70.0:20.0:10.0 | 60.0:20.0:20.0 | 80.0:10.0:10.0 |
| Composition (at %) | In:Ga:Y = | In:Ga:Nd = | In:Ga:Gd = |
| | 62.5:26.5:11.0 | 56.5:27.9:15.6 | 78.0:14.5:7.5 |
| (A + B)/(In + A + B) | 0.375 | 0.435 | 0.220 |
| Bixbyite phase | In₂O₃(Ga is in solid | In₂O₃(Nd, Ga are in solid | In₂O₃(Gd, Ga are in solid |
| | solution state) | solution state) | solution state) |
| Garnet phase | Y₃Ga₅O₁₂ | Nd₃Ga₅O₁₂ | Gd₃Ga₅O₁₂ |
| Maximum particle size of crystals in | 8 | 19 | 5 |
| garnet phase (μm) | | | |
| Electrical resistivity of sintered body | 30 | 600 | 200 |
| (mΩ · cm) | | | |
| Abnormal discharge | Not occurred | Not occurred | Not occurred |
| TFT mobility | 12 | 13 | 22 |
| Carrier concentration (cm⁻³) | 5.0 × 10¹⁵ | 5.0 × 10¹⁴ | 2.0 × 10¹⁶ |
| On/Off ratio | >1 × 10⁶ | >1 × 10⁶ | >1 × 10⁶ |

| | Ex. 10 | Ex. 11 | Ex. 12 |
|---|---|---|---|
| Raw material oxide mixing ratio (wt %) | In₂O₃:Al₂O₃:Y₂O₃ = | In₂O₃:Al₂O₃:Sm₂O₃ = | In₂O₃:Ga₂O₃:Y₂O₃ = |
| | 70.0:15.0:15.0 | 72.9:11.2:15.9 | 78.0:12.2:9.8 |
| Composition (at %) | In:Al:Y = | In:Al:Sm = 58.0:24.3:17.7 | In:Ga:Y = 62.5:26.5:11.0 |
| | 54.1:31.6:14.3 | (+Sn 1000 ppm) | (+Sn 1000 ppm) |
| (A + B)/(In + A + B) | 0.459 | 0.420 | 0.375 |
| Bixbyite phase | In₂O₃(Al is in solid | In₂O₃(Sm, Al are solid | In₂O₃(Ga is solid |
| | solution state) | solution state) | solution state) |
| Garnet phase | Y₃Al₅O₁₂ | Sm₃Al₅O₁₂ | Y₃Ga₅O₁₂ |
| Maximum particle size of crystals in | 10 | 10 | 10 |
| garnet phase (μm) | | | |
| Electrical resistivity of sintered body | 300 | 80 | 20 |
| (mΩ · cm) | | | |
| Abnormal discharge | Not occurred | Not occurred | Not occurred |
| TFT mobility | 13 | 15 | 14 |
| Carrier concentration (cm⁻³) | 5.0 × 10¹⁵ | 7.0 × 10¹⁵ | 5.0 × 10¹⁵ |
| On/Off ratio | >1 × 10⁶ | >1 × 10⁶ | >1 × 10⁶ |

| | Ex. 13 | Ex. 14 | Ex. 15 |
|---|---|---|---|
| Raw material oxide mixing ratio (wt %) | In₂O₃:Al₂O₃:Ce₂O₃ = | In₂O₃:Ga₂O₃:Y₂O₃ = | In₂O₃:Ga₂O₃:Sm₂O₃ = |
| | 57.5:15.8:26.7 | 67.0:12.3:20.8 | 90.7:3.3:6.0 |
| Composition (at %) | In:Al:Ce = 40:30:30 | In:Ga:Y = 50:25:25 | In:Ga:Sm = 83.9:8.1:8.0 |
| | (+Sn 10000 ppm) | | (+Sn 10000 ppm) |
| (A + B)/(In + A + B) | 0.600 | 0.500 | 0.161 |
| Bixbyite phase | In₂O₃(Al is in solid | In₂O₃(Ga is in solid | In₂O₃(Ga, Sm are in solid |
| | solution state) | solution state) | solution state) |
| Garnet phase | Ce₃Al₅O₁₂ | Y₃Ga₅O₁₂ | Sm₃Ga₅O₁₂ |
| Maximum particle size of crystals in | 10 | 10 | 5 |
| garnet phase (μm) | | | |
| Electrical resistivity of sintered body | 700 | 300 | 30 |
| (mΩ · cm) | | | |
| Abnormal discharge | Not occurred | Not occurred | Not occurred |
| TFT mobility | 23 | 23 | 40 |
| Carrier concentration (cm⁻³) | 5.0 × 10¹⁵ | 5.0 × 10¹⁵ | 2.7 × 10¹⁶ |
| On/Off ratio | >1 × 10⁶ | >1 × 10⁶ | >1 × 10⁶ |

TABLE 3

| | Com. Ex. 1 | Com. Ex. 2 | Com. Ex. 3 |
|---|---|---|---|
| Raw material oxide mixing ratio (wt %) | In₂O₃:Ga₂O₃ = | In₂O₃:Al₂O₃ = | In₂O₃:Ga₂O₃ = |
| | 80.0:20.0 | 95.0:5.0 | 95.0:5.0 |
| Composition (at %) | In:Ga = 73.0:27.0 | In:Al = 87.5:12.5 | In:Ga = 92.8:7.2 |
| (A + B)/(In + A + B) | 0.27 | 0.125 | 0.072 |
| Bixbyite phase | In₂O₃(Ga in in solid | In₂O₃(Al is in solid | In₂O₃(Ga is in solid |
| | solution state) | solution state) | solution state) |
| Garnet phase | None | None | None |
| Maximum particle size of crystals in | — | — | — |
| garnet phase (μm) | | | |
| Electrical resistivity of sintered body | 9.0 × 10⁶ | 1.2 × 10⁵ | 8 |
| (mΩ · cm) | | | |
| Abnormal discharge | Occurred | Occurred | Not occurred |
| TFT mobility | Not measured | Not measured | 5 |
| Carrier concentration (cm⁻³) | 4.0 × 10¹⁶ | 5.0 × 10¹⁶ | 1.9 × 10¹⁹ |
| On/Off ratio | Not measured | Not measured | 1.00 × 10² |

| | Com. Ex. 4 | Com. Ex. 5 |
|---|---|---|
| Raw material oxide mixing ratio (wt %) | In₂O₃:Ga₂O₃ = | In₂O₃:Sm₂O₃ = |
| | 98.0:2.0 | 94.1:5.9 |
| Composition (at %) | In:Ga = 97.1:2.9 | In:Sm = 91.9:8.1 |
| (A + B)/(In + A + B) | 0.029 | 0.081 |
| Bixbyite phase | In₂O₃(Ga is in solid | In₂O₃(Sm is in solid |
| | solution state) | solution state) |
| Garnet phase | None | None |
| Maximum particle size of crystals in | — | — |
| garnet phase (μm) | | |
| Electrical resistivity of sintered body | 4 | 1.0 × 10⁵ |
| (mΩ · cm) | | |
| Abnormal discharge | Not occurred | Not occurred |
| TFT mobility | 3 | 5 |
| Carrier concentration (cm⁻³) | 1.5 × 10¹⁹ | 5.0 × 10¹⁸ |
| On/Off ratio | 10.0 | 1.00 × 10⁵ |

### INDUSTRIAL APPLICABILITY

The oxide sintered body of the invention can be used in a sputtering target, and a thin film transistor obtained by using an oxide thin film or the like produced by using the sputtering target of the invention can be preferably applied to integrated circuits such as a field effect transistor, a logic circuit, a memory circuit and a differential gain control circuit. Further, in addition to a field effect transistor, it can be preferably applied to transistors such as a static induction transistor, diodes such as a schottky diode and a resistance device, and so on.

Further, the thin film transistor of the invention can be preferably used in a solar battery, displays such as liquid crystal displays, organic electroluminescence devices and inorganic electroluminescence devices and an electronic apparatus using them.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

1. An oxide sintered body comprising a bixbyite phase composed of In₂O₃ and an A₃B₅O₁₂ phase (wherein A is one or more elements selected from the group consisting of Sc, Y, La, Ce, Pr, Nd, Pm, Sm, Eu, Gd, Tb, Dy, Ho, Er, Tm, Yb and Lu, and B is one or more elements selected from the group consisting of Al and Ga).

2. The oxide sintered body according to claim 1, wherein A is one or more elements selected from the group consisting of Y, Ce, Nd, Sm, Eu and Gd.

3. The oxide sintered body according to claim 1, wherein either one or both of the element A and the element B is (are) in a substitutional solid solution state in the bixbyite phase.

4. The oxide sintered body according to claim 1, wherein the atomic ratio of indium, the element A and the element B contained in the oxide sintered body, (A+B)/(In+A+B), is 0.01 to 0.50.

5. The oxide sintered body according to claim 1, wherein the electrical resistivity is 1 mΩcm or more and 1000 mΩcm or less.

6. A method for producing an oxide sintered body comprising the steps of:
preparing mixture powder by mixing raw material powder comprising indium, raw material powder comprising A which is one or more elements selected from the group consisting of Sc, Y, La, Ce, Pr, Nd, Pm, Sm, Eu, Gd, Tb, Dy, Ho, Er, Tm, Yb and Lu and raw material powder comprising B which is one or more elements selected from the group consisting of Al and Ga;
shaping the mixture powder to produce a shaped body; and
firing the shaped body at 1200° C. to 1650° C. for 10 hours or longer.

7. The method for producing an oxide sintered body according to claim 6, wherein an atomic ratio (A+B)/(In+A+B) of the mixture powder is 0.01 to 0.50.

8. A sputtering target obtained by using the oxide sintered body according to claim 1.

9. An oxide thin film formed by using the sputtering target according to claim 8.

10. A thin film transistor in which the oxide thin film according to claim 9 is used.

11. The oxide sintered body according to claim 1, wherein the maximum particle size of crystals of the A₃B₅O₁₂ phase is 20 μm or less.

12. The thin film transistor according to claim 10, wherein the thin film transistor is a channel-doped type thin film transistor.

13. An electronic apparatus in which the thin film transistor according to claim 10 is used.
